(19) United States
(12) Patent Application Publication
(10) Pub. No.: US 2014/0355205 A1
(43) Pub. Date: Dec. 4, 2014

(54) ELECTRONIC DEVICE WITH AIR DUCT

(71) Applicant: HON HAI PRECISION INDUSTRY CO., LTD., New Taipei (TW)

(72) Inventor: YAO-TING CHANG, New Taipei (TW)

(73) Assignee: HON HAI PRECISION INDUSTRY CO., LTD., New Taipei (TW)

(21) Appl. No.: 14/142,950

(22) Filed: Dec. 30, 2013

(30) Foreign Application Priority Data
May 31, 2013 (TW) 102119411

(51) Int. Cl. H05K 7/20

(52) U.S. Cl. CPC H05K 7/20709; H05K 7/20145
USPC 361/679.54; 165/80.2

(57) ABSTRACT

An electronic device includes a motherboard, a heat-generation element mounted on the motherboard, a heat sink attached on the heat-generation element, and an air duct located on the motherboard and covering the heat sink. The air duct includes a main body and an air baffle detachably mounted to the main body. The main body includes a top board, and a first side board and a second side board extending down from two opposite sides of the top board. The top board defines an opening adjacent to the second side board. The air baffle is detachably inserted into the opening.

### BACKGROUND

1. Technical Field

The disclosure relates to electronic devices and, particularly, to an electronic device comprising an air duct for guiding airflow.

2. Description of Related Art

In a server system with multi central processing units (CPUs), an area not yet having a CPU will form a low impedance area without a heat sink. As a result, a great amount of airflow will flow through the area, which may influence heat dissipation of the server. To solve this problem, a dummy heat sink may be installed in the area, which is costly. Therefore, there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an embodiment of an electronic device, wherein the electronic device comprises a central processing unit and an air duct.

FIG. 2 is an assembled isometric view of FIG. 1.

FIG. 3 is an isometric, exploded view of another embodiment of an electronic device, wherein the electronic device comprises two central processing units.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one”.

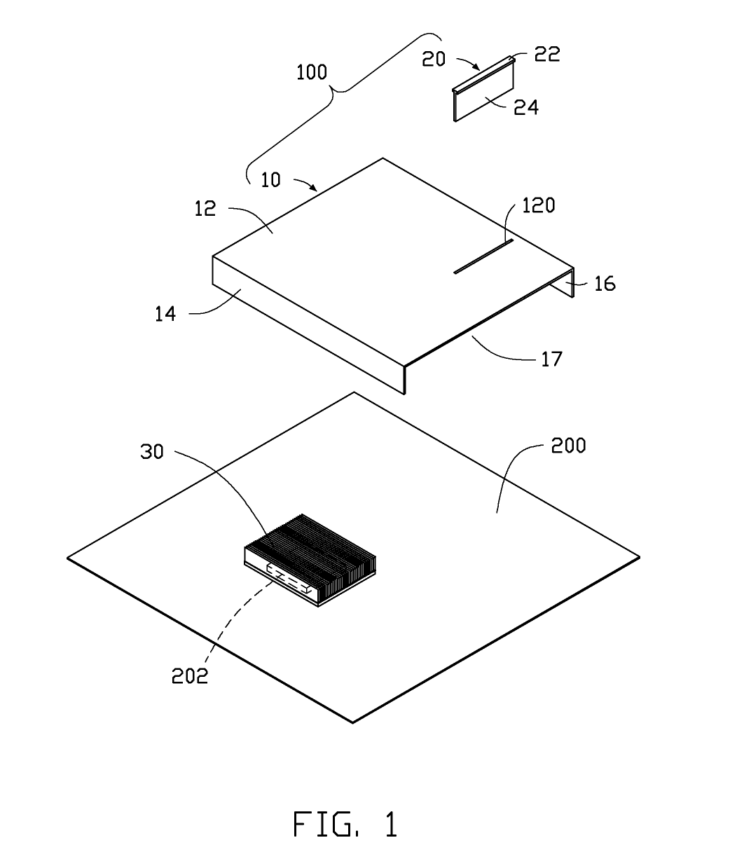

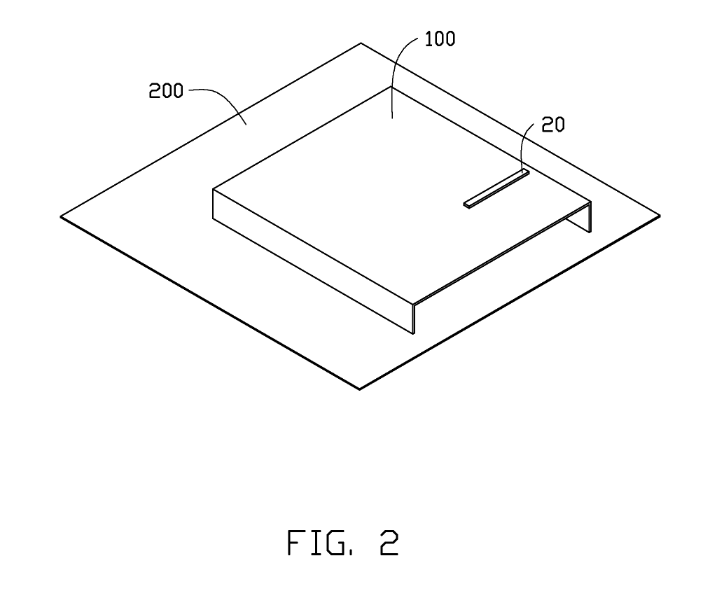

FIGS. 1 and 2 show an embodiment of an electronic device. The electronic device comprises a motherboard 200, a heat-generation element 202 mounted on the motherboard 200, a heat sink 30 attached on the heat-generation element 202, and an air duct 100 located on the motherboard 200 and covering the heat sink 30. In one embodiment, the heat-generation element 202 is a central processing unit (CPU).

The air duct 100 comprises a main body 10 and an air baffle 20 detachably mounted to the main body 10. The main body 10 comprises a top board 12, and a first side board 14 and a second side board 16 extending down from opposite sides of the top board 12. The top board 12, the first side board 14, and the second side board 16 cooperatively bound an airflow channel 17. The top board 12 defines a long and narrow opening 120 adjacent to the second side board 16. The air baffle 20 is mountably received in the opening 120.

In the illustrated embodiment, the air baffle 20 is substantially T-shaped and comprises an abutting plate 22 and a blocking plate 24 extending substantially perpendicularly down from the abutting plate 22.

In use, the blocking plate 24 is received through the opening 120 of the main body 10, and the abutting plate 22 abuts against the top board 12. A bottom surface of the blocking plate 24 is supported on the motherboard 200. Thus, the blocking plate 24 can block airflow at the side of the airflow channel 17 adjacent to the second side board 16.

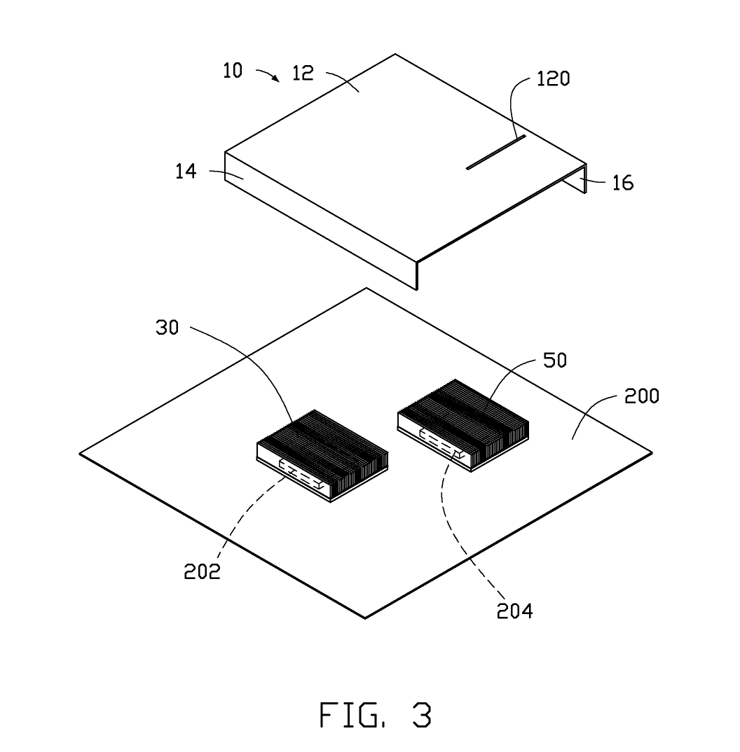

Referring to FIG. 3, in another embodiment, when the motherboard 200 comprises another heat-generation element 204 adjacent to the second side board 16, and another heat sink 50 attached on the heat-generation element 204, the air baffle 20 can be omitted from the main body 10.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An air duct, comprising:
a main body comprising a top board, and a first side board and a second side board extending down from opposite sides of the top board, the top board defining an opening adjacent to the second side board; and
an air baffle detachably inserted into the opening.

2. The air duct of claim 1, wherein the air baffle comprises an abutting plate abutting against a top of the top board, and a blocking plate extended down from the abutting plate, the blocking plate is extended through the opening.

3. The air duct of claim 1, wherein the opening extends in a direction from the first side board to the second board.

4. The air duct of claim 3, wherein the opening is perpendicular to the second side board.

5. An electronic device, comprising:
a motherboard;
a heat-generation element mounted on the motherboard;
a heat sink attached on the heat-generation element; and
an air duct located on the motherboard and covering the heat sink, wherein the air duct comprises a main body and an air baffle detachably mounted to the main body, the main body comprises a top board, and a first side board and a second side board extending down from opposite sides of the top board, the top board defining an opening adjacent to the second side board, the air baffle detachably inserted into the opening;

6. The electronic device of claim 5, wherein the air baffle comprises an abutting plate abutting against a top of the top board, and a blocking plate extended down from the abutting plate, the blocking plate is extended through the opening.

7. The electronic device of claim 5, wherein the opening extends in a direction from the first side board to the second board.

8. The electronic device of claim 7, wherein the opening is perpendicular to the second side board.
